(19) United States
(12) Patent Application Publication
(10) Pub. No.: US 2025/0257459 A1
(43) Pub. Date: Aug. 14, 2025

(54) Precursor Delivery System

(71) Applicant: Egbert Woelk, North Andover, MA (US)

(72) Inventor: Egbert Woelk, North Andover, MA (US)

(73) Assignee: CeeVeeTech LLC, Peabody, MA (US)

(21) Appl. No.: 18/438,841

(22) Filed: Feb. 12, 2024

(51) Int. Cl. C23C 16/455

(52) U.S. Cl. CPC C23C 16/45544; C23C 16/45557

(57) ABSTRACT

A precursor delivery system that injects a reactive first fluid stream into a second inert fluid stream for a predetermined period of time. The second fluid stream is directed toward the surface of a substrate. The precursor that is injected with the first fluid stream can chemically react with the surface of the substrate. The predetermined period of time of the injection and the partial pressure of the precursor determines the properties of a solid layer that is formed on the substrate. A temperature deviation of the precursor introduces an evaporation and partial pressure error. The predetermined period of time of the injection is adjusted to compensate for the temperature deviation of the precursor. The duration of the injection is further measured by a pressure sensor on the injection valve.

### CROSS-REFERENCE TO RELATED APPLICATIONS

This application claims the benefit of U.S. Provisional Application No. 63/484,562, filed Feb. 13, 2023, entitled “Precursor Delivery System,” the entire contents of which is hereby incorporated herein by reference.

### PRIOR ART

U.S. Pat. No. 11,560,624 B2

### BACKGROUND OF THE INVENTION

Chemical Vapor Deposition CVD and Atomic Layer Deposition ALD and Atomic Layer Etching ALE rely on the sequencing of multiple controlled fluid streams. These fluid streams are generally gaseous. The apparatus that is used for CVD, ALD, and ALE provides the plumbing to generate a plurality of such controlled fluid streams-such as suitable controls, conduits, meters, transducers, pumps, heating and cooling. Generally, the largest of those streams is a continuous stream of a gas that is chemically inert with respect to the CVD, ALD, and ALE process under consideration. This fluid stream is called the main fluid stream and has a predetermined velocity. Further, the apparatus provides the plumbing to add a plurality of reactive fluid streams to the main fluid stream for individually predetermined amounts of time. This results in a composite fluid steam. The apparatus provides tubing and pipes to direct this composite fluid stream across a surface of a substrate that is located inside a reaction chamber which is also part of the apparatus. The composition of the composite fluid stream changes according to the predetermined combination of the individual streams. Further, the apparatus provides a means to maintain the substrate at a predetermined temperature.

The composite fluid stream chemically reacts with the surface of the substrate. In CVD and ALD the reaction forms a solid material layer. The thickness of this layer or the coverage of the substrate with respect to a constituent that makes up the layer is proportional to the partial pressure of the respective precursor in the fluid stream and the time that this precursor is present in the composite fluid stream.

In CVD and ALD the composition of the solid layer that is formed in this process can be controlled by two methods. A first method comprises the exposure of the substrate to a fluid stream of a predetermined composition. The constituent atoms of the solid layer are incorporated proportional to their reactivity with the substrate surface and their partial pressure in the stream.

A second method comprises the sequential exposure of the substrate to only one precursor at a time. The exposure to a first precursor for a first predetermined period of time is followed by the exposure to a second precursor for a second predetermined period of time followed by the exposure to a third, fourth or more precursors as needed to make the desired solid layer.

In ALE the chemical reaction removes material layers from the surface. The amount of material removed depends on the partial pressure of a reactive gas in the gas phase. The exposure to a first reactive gas (called a first precursor in CVD and ALD terms) forms a first activated surface on a substrate. The subsequent exposure of the first activated surface to a second reactive gas (precursor) removes one layer of the material of the substrate and restores the initial surface and the cycle is repeated.

The CVD, ALD and ALE apparatus provides the sensors and actuators to set a predetermined pressure in the reaction chamber. The pressure of the streams inside the reactor chamber ranges from 50 Pa to 100,000 Pa and the velocity of the stream normal to a cross section of the reaction chamber ranges from 0.01 m s⁻¹ to 10 m s⁻¹.

### SUMMARY OF THE INVENTION

The invention is used in the field of Chemical Vapor Deposition and Atomic Layer Deposition and more broadly in any application where a fluid stream that contains one or more reactive chemicals covers or modifies the surface of a substrate. The invention describes an apparatus and a method to compensate for an error in the partial pressure of a reactive species in the fluid stream. The compensation is based on the theory that for a chemical vapor deposition and for an atomic layer deposition the number hits by reactive gas species on the surface of the substrate needs to be precisely controlled. The present invention measures the concentration of a given species in the gas phase by measuring the vapor pressure of the liquid or solid source of that species. It subsequently divides a predetermined nominal (also recipe, target, intended) concentration by the measured concentration to obtain a factor f. Analysis yields that f is the [vapor pressure of source at nominal temperature] divided by the [vapor pressure of source at the measured temperature]. The factor f is subsequently applied to the nominal (also recipe, target, intended) duration of exposure pulse. In other words: if the concentration (or temperature) of a precursor species is higher then intended the time of the exposure time to the substrate surface is shortened accordingly. If the concentration (or temperature) of a precursor species is lower than intended the exposure time to the substrate is extended.

### BRIEF DESCRIPTION OF DRAWINGS

FIG. 1 shows a first embodiment of a precursor delivery system

FIG. 2 shows the compensation principle

FIG. 3 shows a second embodiment of a precursor delivery system

FIG. 4 shows the flow diagram for a method to operate a precursor delivery system

FIG. 5 shows the response of a fast acting shut-off valve to a pneumatic pilot pulse

### DETAILED DESCRIPTION OF THE INVENTION

A delivery system 100 is capable to deliver a precursor 130 to an CVD or ALD process. The precursor 130 is stored in an ampoule 136 that has at least one inlet 111 and one outlet 112. The precursor 130 can either be liquid or solid at the temperature at which it is stored inside ampoule 136. The ampoule 136 is located inside a temperature-controlled enclosure 137. A carrier gas stream 113 can be admitted to the ampoule via the inlet 111. The carrier gas stream 113 is varied so that the fluid in the headspace of ampoule 136 is maintained at a predetermined pressure. A temperature sensor 135 is located inside the ampoule 136. The vapor over the precursor 130 is thus entrained in a first fluid stream 110 that consists of the carrier gas and the precursor vapor. The first fluid stream 110 that contains the precursor vapor is contained in a suitable conduit that connects the outlet 112 of ampoule 136 with a flow controlling device 117. The flow controlling device 117 is in fluid communication with a fast-acting shut-off valve 150. A second fluid stream 120 is contained by a suitable conduit that is in fluid communication with the fast-acting shut-off valve 150 and a reaction chamber 140. The fast acting shut-off valve 150 can be opened by an electric control pulse that is provided by a pulse controller 200. A sensor-of-state 160 is connected to the stem of the fast-acting shut-off valve 150. The sensor-of-state 160 is in communication with the pulse controller 200 and is configured to transmit a signal that indicates the state of the fast-acting valve 150.

The pulse controller 200 comprises at least seven functional blocks: an interface 204 for the fast-acting shut-off valve 150, an interface 208 for the sensor-of-state 160, an interface 212 for the temperature sensor 135, an interface 214 for a control unit of a CVD or ALD apparatus 300, a mass storage device 210, such as an SD card, an input and display device 202, all of which are connected individually to a microcontroller unit (MCU) 206.

The MCU 206 is configured so that a nominal temperature Tₙₒₘᵢₙₐₗ can be stored and is available for computations. Further, the pulse controller is configured so that a plurality of vapor pressure curves can be stored, one of them being the vapor pressure curve of the specific precursor 130. Further, the MCU 206 is configured to measure the length of and electrical pulse that it receives from the control unit of a CVD, ALD, or ALE apparatus 300. The MCU 206 is further capable to execute the required computations. It is capable to display computed data and other information on the display device 202 store computed data on the mass storage device 210.

In operation the second fluid stream 120 is set at an invariable predetermined velocity v. Provided that the pressure in the second fluid stream 120 is lower than the pressure in the first fluid stream 110, the opening of the fast-acting shut-off valve 150 for a predetermined amount of time t generates a precursor pulse 125 of a predetermined length in the second fluid stream 120. The time of the opening is called the exposure time t. The spatial length x of the precursor pulse 125 is given by the formula x=v*t. The partial pressure pp of the precursor in the precursor pulse 125 is determined by the temperature of the precursor 130 in ampoule 136. A temperature sensor 135 is immersed in the liquid or solid precursor 130 to obtain the precursor temperature. The temperature sensor 135 is in communication with the pulse controller 200. The temperature sensor 135 is configured to measure the temperature at least at one but generally at more than one points within the precursor 130 and inside ampoule 136. Specifically, the measurement of the temperature at five different points may be useful to determine the temperature uniformity inside the bulk of the precursor 130 and the headspace 115. As many as ten different points may be useful to measure a temperature field inside the ampoule136 or more generally in the thermal enclosure 137.

The second fluid stream 120 with the precursor pulse 125 is directed toward the surface of a substrate142 inside the reaction chamber 140. The flow velocity v of the second fluid stream 120 and the precursor pulse 125 may change as they travel through the precursor delivery system 100. The spatial pulse length of the pulse 125 increases when the cross section of the second fluid stream 120 is reduced and decreases when the cross section of the second fluid stream is widened. The exposure time t=x/v that the pulse is present at any given cross section of the second fluid stream 120 remains constant. The flow velocity of the second fluid stream normal to the cross section of the reactor chamber 140 may be ranging from 0.01 m s⁻¹ to 10 m s⁻¹.

The total pressure of the second fluid stream 120 may change while it travels through the precursor delivery system 100. The pressure of the second fluid stream 120 inside the reaction chamber 140 can be in the range from 10 Pa to 100,000 Pa.

The partial pressure pp of the precursor in precursor pulse 125 is proportional to the vapor pressure vp of the precursor 130 at a temperature T and can be presented as pp=const*vp(T). The vapor pressure vp of the precursor 130 is a function of the temperature of the surface of the precursor 130 in side ampoule 136. The measurement of the temperature of the precursor 130 near evaporating surface can be used to compute the vapor pressure vp and the partial pressure pp of the precursor in the precursor pulse 125. In general, when designing a CVD or ALD process, a nominal partial pressure ppₙₒₘᵢₙₐₗ in the precursor pulse 125 is calculated from a nominal temperature Tₙₒₘᵢₙₐₗ.of precursor 130. When the precursor 130 is at that nominal temperature Tₙₒₘᵢₙₐₗ the partial pressure ppₙₒₘᵢₙₐₗ of the precursor in the precursor pulse 125 is precisely what the CVD or ALD process requires to form a perfect layer. The temperature controlled enclosure 137 is generally set to the nominal temperature Tₙₒₘᵢₙₐₗ. Those skilled in the art know that for a number of reasons the precursor is almost never at the nominal temperature. The difference between the measured temperature T_{measured} of the precursor and the nominal temperature Tₙₒₘᵢₙₐₗ of the process design can be as large as +/−10 degrees C. and not uniform throughout the bulk of the precursor 130.

In operation of the precursor delivery system 100, the pulse controller 200 continuously collects the measurements from temperature sensor 135 inside the ampoule and stores them to be available for computations. The pulse controller 200 is programmed to determine the temperature T_{measured} that is most closely related to the evaporation or sublimation of precursor 130. A first method to determine T_{measured} is to take the coldest of the plurality of temperatures. A second method to determine T_{measured} is to take the average of the temperatures at each of the points of temperature sensor 135. Evaporation and sublimation require heat. This heat is taken from the solid or liquid precursor 130 close to the surface where the evaporation takes place. This makes the surface of the precursor the coldest point inside ampoule 136. When using the first method to determine T_{measured} it is the temperature of a point that is closest to a surface where evaporation takes place and determines the vapor pressure and the partial pressure of the precursor in precursor pulse 125.

In operation, T_{measured} of the precursor source 100 shifts for various reasons. One of these reasons is the consumption of the precursor 130. This leads to a change in the geometry of the precursor with the associated change in heat flows and temperature. Another reason is a change of precursor delivery system 100 from an idle state in which no precursor is drawn to a use state in which precursor is drawn. After that change the temperature inside the precursor 130 settles into a new steady state. It takes anywhere from 30 to 120 minutes for the precursor 130 to reach the new steady state. The often used approximation that Tₙₒₘᵢₙₐₗ equals T_{measured} at all times is only valid in a few instances.

The unintended deviation of T_{measured} from the nominal temperature Tₙₒₘᵢₙₐₗ and the associated deviation from the nominal partial pressure ppₙₒₘᵢₙₐₗ of the precursor in precursor pulse 125 lead to the growth of an material layer which is different from one that the nominal process would have yielded. A compensation mechanism is needed that compensates for the deviation of partial pressure pp over the substrate 142 from the nominal partial pressure PPₙₒₘᵢₙₐₗ

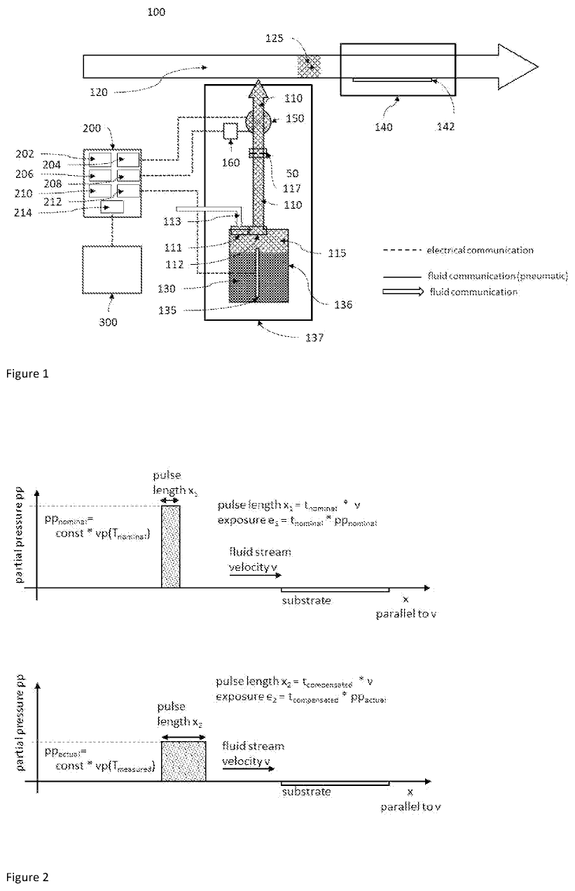

FIG. 2 illustrates the underlying principle for providing this compensation. The growth rate of a layer and the speed at which one mono layer is formed proportional to the partial pressure pp of the precursor in the precursor pulse 125. The effect of precursor pulse on the surface is e=pp*t. The CVD or ALD process is designed to achieve effect e=ppₙₒₘᵢₙₐₗ*tₙₒₘᵢₙₐₗ. The precursor 130 is at temperature T_{measured} which produces a partial pressure in precursor pulse 125 of pp_{actual}=const*vp(T_{measured}). instead of ppₙₒₘᵢₙₐₗ=const*vp(Tₙₒₘᵢₙₐₗ). In order to achieve the same effect e on the surface, e=const*vp(Tₙₒₘᵢₙₐₗ)*tₙₒₘᵢₙₐₗ=const*vp(T measured)*t_{compensated}. This gives the compensated pulse length t_{compensated}=tₙₒₘᵢₙₐₗ*vp(Tₙₒₘᵢₙₐₗ)/vp(T_{measured}). A lower than intended partial pressure pp is thus compensated by a proportionally longer pulse length. The effect e can be measured as the layer thickness or by the coverage in percent in case of a deposition of less than one atomic layer or possibly by some other measurements.

The compensation is provided by the precursor delivery system 100 of this disclosure. The pulse controller 200 is programed to calculate a compensated pulse length t_{compensated} according the formula t_{compensated}=tₙₒₘᵢₙₐₗ*vp(Tₙₒₘᵢₙₐₗ)/vp(T_{measured}).

In first embodiment of FIG. 1. the fast-acting shut-off valve 150 is configured with a solenoid actuator. The sensor-of-state 160 is configured as a continuous linear position sensor. The sensor-of-state 160 may also be configured as a two-point position sensor.

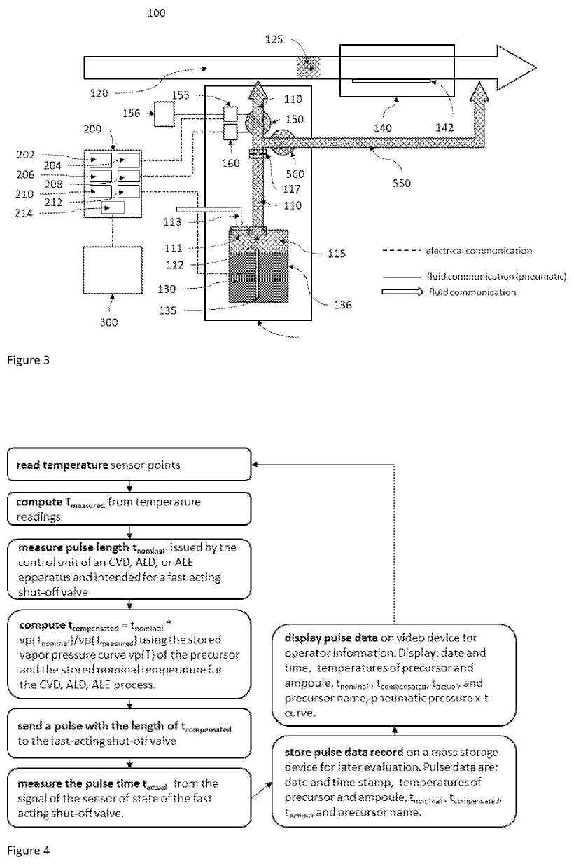

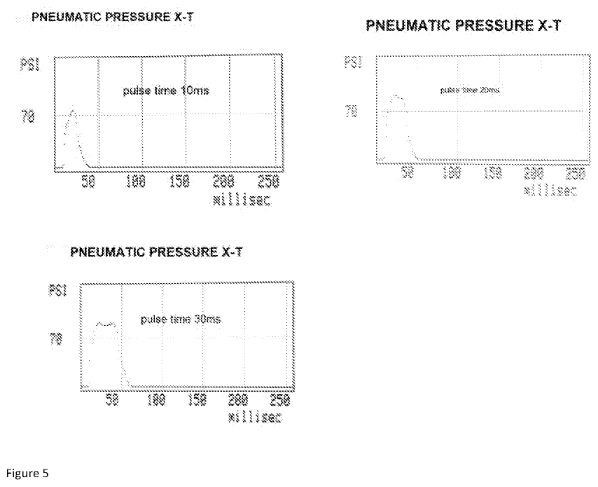

In a second embodiment as shown in FIG. 3. the fast acting shut-off valve 150 is configured with a pneumatic actuator. The pneumatic actuator of valve 150 is in pneumatic communication with a pilot valve 155. The pilot valve 155 is a solenoid valve that is also in pneumatic communication with a pneumatic pressure supply 156. Further, the pneumatic actuator of fast-acting shut-off valve 150 is in pneumatic communication with the sensor-of-state 160. In the embodiment represented in FIG. 3 the sensor-of-state is a pressure transducer. The pressure transducer as a sensor-of-state to the fat-acting shut-off valve sends a pressure signal to the pulse controller 200. The pneumatic pressure in the actuator of a pneumatically driven valve is an indication for the state of the valve. When the pneumatic pressure exceeds a specific pressure (that is provided by the manufacturer of the valve) the valve is guaranteed to be open.

The pulse controller 200 is programmed to measure the time that passes between the moment when the pressure transducer 160 exceeds the specific opening pressure of the fast acting shut-off valve 150 and the moment when it falls below it. This length of time is called the actual pulse time t_{actual}. t_{actual} should always be equal to t_{compensated} when the pulse time is longer than 10 milliseconds. Otherwise a problem with the fast acting shut-off valve 150 can be detected. For a pulse time of less than 10 milliseconds t_{actual} can be used for analyzing the response of the fast acting shut-off valve. FIG. 5 shows the pneumatic response to a 10, 20, and 30 millisecond pulse time. The combination of pneumatic pilot valve and pneumatic actuator stops responding to pulse times shorter than 3 milliseconds. The pneumatic solenoid valve is unable to open for such short periods of time.

Further, in the second embodiment the precursor delivery system 100 comprises a waste fluid stream 550. A fast acting shut-off valve 560 controls the waste fluid stream 550. The fast acting shut-off valve 560 is operated inversely to fast-acting shut-off valve 150. This means that the fast acting shut-off valve 560 is open when fast acting shut-off valve is closed and vice versa. The waste fluid stream 550 enables a steady state stream through the ampoule 130 and eliminates transients of the first fluid stream 110 between zero flow and the flow that is determined by the adjustable flow controlling device 117. The waste fluid stream 550 joins the second fluid stream 120 downstream of the reaction chamber 140.

1. A precursor delivery system comprising:
a precursor source comprising an ampoule configured to contain a liquid or solid precursor, the ampoule having an inlet and an outlet;
a pulse controller configured to measure the duration of a valve control pulse, further configured to drive a fast valve, further configured to receive a signal from a temperature sensor, further configured to receive a sensor-of-state of a fast valve;
a fast-acting shut-off valve driven by the pulse controller, the upstream side of the fast valve being in fluid communication with the outlet of the ampoule through a suitable conduit, the downstream side of the fast valve being in fluid communication with a second fluid stream contained by a suitable conduit;
a temperature sensor being immersed in the precursor inside the ampoule, and the temperature sensor being in communication with the pulse controller; and
a sensor-of-state of the fast valve being in communication with the pulse controller.

2. A precursor delivery system according to claim 1. that uses a temperature sensor comprising a plurality of measurement points along a line, the cross section normal to the line not exceeding 12 square millimeters, and each of the measurement points having a temperature resolution of less than 30 milli Kelvin.

3. A precursor delivery system according to claim 2, where the temperature sensor is immersed in a precursor so that at least one of the plurality of measurement points is not more than 20 millimeters from the of the surface of the precursor.

4. A precursor delivery system according to claim 1, where the fast valve is a pneumatically driven valve with a specified pneumatic pressure for operation.

5. A precursor delivery system according to claim 1.that uses a solenoid valve to generate an pneumatic pilot pulse for the pneumatic fast valve.

6. A precursor delivery system according to claim 1. that uses a fast pressure transducer as a sensor-of-state for a pneumatic fast valve, the pressure transducer being configured to have a resolution of at least 0.5 psi (3.4 kPa) and a response time of not more than 0.5 milliseconds.

7. A method for exposing a surface to a precursor comprising:
to generate a first fluid stream consisting of a carrier fluid and a vapor from a liquid or solid precursor being generated by evaporation or sublimation;
to establish a nominal temperature Tₙₒₘᵢₙₐₗ for the precursor;
to generate a second fluid stream with a predetermined velocity;
to add the first fluid stream to the second fluid stream for a predetermined length of time tₙₒₘᵢₙₐₗ when the precursor is at the nominal temperature Tₙₒₘᵢₙₐₗ; and
to direct the combined fluid stream across the surface of a substrate.

8. A method according to claim 7 where a temperature T_{measured} is tis measured inside the bulk of a precursor;
where the nominal control pulse length tₙₒₘᵢₙₐₗ is measured, with tₙₒₘᵢₙₐₗ being in the range from 0.1 (zero point one) millisecond, 1 (one), 10 (ten), 100 (hundred), 1000 (thousand) to 10000 (ten thousand) milliseconds;
where a compensated control pulse length t_{compensated} is computed from the nominal control pulse length tₙₒₘᵢₙₐₗ, the nominal temperature Tₙₒₘᵢₙₐₗ, and the measured temperature T measured by using the temperature dependent vapor pressure vp(T) of the precursor according the formula
t_{compensated}=tₙₒₘᵢₙₐₗ*vp(Tₙₒₘᵢₙₐₗ)/vp(T_{measured}); and
where the first fluid stream is added to the second fluid stream for the compensated control pulse length t_{compensated} instead of the nominal control pulse length tₙₒₘᵢₙₐₗ.

9. A method of claim 7 where the precursor in the combined fluid stream can chemically react with a surface of a substrate to form a solid.

10. A method according to claim 8 where the precursor in the combined fluid stream chemically reacts with the surface to form a liquid.

11. A method according to claim 8 where the molar concentration c of the vapor in the first fluid stream is in a range between 0.1% and 95%.

12. A method according to claim 8 where the actual pulse length t_{actual} is determined as the interval between the time when the pilot pressure rises above the operating pressure of the pneumatic fast valve and the time when the pilot pressure drops below the operating pressure of the pneumatic fast valve.
